(19) United States
(12) Patent Application Publication
(10) Pub. No.: US 2017/0094787 A1
(43) Pub. Date: Mar. 30, 2017

(54) PRINTED CIRCUIT BOARD AND ELECTRONIC APPARATUS

(71) Applicant: SAMSUNG ELECTRONICS CO., LTD., Suwon-si (KR)

(72) Inventors: Sung-yong JOO, Hwaseong-si (KR); Jin-hyung LEE, Anyang-si (KR)

(73) Assignee: SAMSUNG ELECTRONICS CO., LTD., Suwon-si (KR)

(21) Appl. No.: 15/255,899

(22) Filed: Sep. 2, 2016

(30) Foreign Application Priority Data
Sep. 25, 2015 (KR) 10-2015-0136512

(51) Int. Cl. H05K 1/03; H05K 1/09; H05K 1/02; H05K 1/18

(52) U.S. Cl. CPC H05K 1/0366; H05K 1/181; H05K 1/09; H05K 1/0298; H05K 2201/0104

(57) ABSTRACT

Disclosed is a printed circuit board, to which at least one circuit device is mountable, including a base layer with a plurality of paper layers; a waterproof insulation layer laid on a first surface of the base layer; a copper foil layer laid on a second surface opposite to the first surface of the base layer and printed with a signal line pattern connectable with the at least one circuit device; and an adhesive layer configured to be interposed between the base layer and the copper foil layer that includes an adhesive material for adhering the base layer and the copper foil layer.

### CROSS-REFERENCE TO RELATED APPLICATION

This application claims priority from Korean Patent Application No. 10-2015-0136512 filed on Sep. 25, 2015 in the Korean Intellectual Property Office, the disclosure of which is incorporated herein by reference.

### BACKGROUND

Field

Apparatuses and methods consistent with the exemplary embodiments relate to a printed circuit board and an electronic apparatus, such as a display apparatus and a power supply, in which a printed circuit board includes an insulation layer for blocking moisture from the outside.

Description of the Related Art

In a television (TV), if a top or bottom side of a printed circuit board (PCB) is exposed to moisture, the moisture may interfere with insulation of parts.

In case of the PCB generally used in the TV and made of a composite epoxy material (CEM)-1, upper and lower layers of the PCB include an insulation layer of textile fiber in order to block moisture from the outside.

The PCB made of the CEM-1 can block the moisture since the textile fiber is applied to an upper layer side to be mounted with parts and a lower layer side having copper foil. However, the cost is high if the textile fiber is applied to large-sized electronics.

### SUMMARY

Accordingly, exemplary embodiments may provide a printed circuit board and an electronic apparatus, in which an insulation layer and an adhesive layer are respectively applied to an upper layer and a lower layer of the printed circuit board, thereby preventing insulating properties from changing due to moisture.

Another aspect is to provide a printed circuit board and an electronic apparatus, in which, rather than textile fiber material, a resin material having waterproof and adhesive functions is applied to a lower layer of the printed circuit board, thereby reducing manufacturing costs of the printed circuit board.

In accordance with an exemplary embodiment, there is provided a printed circuit board, to which at least one circuit device is mountable, including: a base layer with a plurality of paper layers; a waterproof insulation layer laid on a first surface of the base layer; a copper foil layer laid on a second surface opposite to the first surface of the base layer and printed with a signal line pattern connectable with the at least one circuit device; and an adhesive layer interposed between the base layer and the copper foil layer that includes an adhesive material that adheres the base layer and the copper foil layer.

In the printed circuit board according to this exemplary embodiment, the insulation layer may be applied to the upper layer of the substrate, and the resin material having the waterproof and adhesive functions may be applied to the lower layer of the substrate, thereby blocking moisture from the outside. Further, instead of the textile fiber material, the resin material having the waterproof and adhesive functions may be applied to the lower layer of the substrate, thereby reducing costs.

The waterproof insulation layer may include a textile fiber material. Thus, the upper layer of the printed circuit board may include an insulation layer made of a woven glass fiber material, thereby preventing insulating properties from changing due to moisture.

The adhesive layer may include a waterproof material. The waterproof material may include an insulating resin material. The adhesive material may include a semi-hardening epoxy resin material. In such a case, the semi-hardening epoxy resin material is applied to the lower layer of the printed circuit board to thereby stick together the base layer and the copper foil layer. Further, the resin material is applied to the lower layer of the printed circuit board to thereby block moisture from the outside.

The adhesive layer may be formed as a single layer by combining the adhesive material and the waterproof material. Thus, a single layer, where one or more resin materials are combined, having an adhesive or waterproof function is applied to the lower layer of the printed circuit board, having both the adhesive and waterproof functions with a simple structure.

The adhesive layer may be hardened by heating at high temperature to stick together the base layer and the copper foil layer. In such a case, the semi-hardening epoxy resin material is interposed in between the base layer and the copper foil layer of the printed circuit board and heated at high temperature so that the base layer and the copper foil layer can be stuck together.

The waterproof insulation layer and the waterproof adhesive layer may include an insulating material to have a comparative tracking index (CTI) equal to or higher than a predetermined value. In such a case, the textile fiber material is applied to the upper layer of the printed circuit board, and the semi-hardening epoxy resin material is applied to the lower layer, thereby providing good insulating properties.

The base layer may include an epoxy resin material. In such a case, the epoxy resin material is applied to the plurality of paper layers of the printed circuit board, and the base layer is thus more resistant to moisture than materials containing phenol resin.

In accordance with an embodiment, there is provided an electronic apparatus with a printed circuit board including a power supply for receiving an alternating current (AC) power signal and supplying operation power to the electronic apparatus, the printed circuit board including: a base layer with a plurality of paper layers; a waterproof insulation layer laid on a first surface of the base layer; a copper foil layer laid on a second surface opposite to the first surface of the base layer and printed with a signal line pattern connectable with the at least one circuit device; and an adhesive layer interposed between the base layer and the copper foil layer that includes an adhesive material that adheres the base layer and the copper foil layer.

In the printed circuit board according to this exemplary embodiment, the insulation layer of the textile fiber material may be applied to the upper layer of the substrate, and the resin material having the waterproof and adhesive functions may be applied to the lower layer of the substrate, thereby blocking moisture from the outside. Further, instead of the textile fiber material, the resin material having the waterproof and adhesive functions is applied to the lower layer of the substrate, thereby reducing manufacturing costs.

The waterproof insulation layer may include a textile fiber material. Thus, the upper layer of the printed circuit board includes the insulation layer made of a woven glass fiber material, thereby preventing insulating properties from changing due to moisture.

The adhesive layer may include a waterproof material. The waterproof material may include an insulating resin material. The adhesive material may include a semi-hardening epoxy resin material. Thus, the semi-hardening epoxy resin material may be applied to the lower layer of the printed circuit board to thereby stick together the base layer and the copper foil layer. Further, the resin material may be applied to the lower layer of the printed circuit board to thereby block moisture from the outside.

The adhesive layer may be formed as a single layer by combining the adhesive material and the waterproof material. Thus, a single layer, where one or more resin materials are combined, having an adhesive or waterproof function may be applied to the lower layer of the printed circuit board, having both the adhesive and waterproof functions with a simple structure.

The adhesive layer may be hardened by heating at high temperature to stick together the base layer and the copper foil layer. Thus, the semi-hardening epoxy resin material may be interposed in between the base layer and the copper foil layer the printed circuit board and heated at high temperature so that the base layer and the copper foil layer can be stuck together.

The waterproof insulation layer and the adhesive layer may include an insulating material to have a comparative tracking index (CTI) equal to or higher than a predetermined value such as 600 V. Thus, the textile fiber material is applied to the upper layer of the printed circuit board, and the semi-hardening epoxy resin material is applied to the lower layer, thereby providing good insulating properties.

The base layer may include an epoxy resin material. In such a case, the epoxy resin material is applied to the plurality of paper layers of the printed circuit board, and the base layer is more resistant to moisture than materials containing phenol resin.

### BRIEF DESCRIPTION OF THE DRAWINGS

The above and/or other aspects will become apparent and more readily appreciated from the following description of exemplary embodiments, taken in conjunction with the accompanying drawings, in which:

FIG. 1 is a block diagram of a display apparatus according to an exemplary embodiment;

FIG. 2 is a block diagram of an electronic apparatus according to an exemplary embodiment;

FIG. 3 illustrates a conventional single-side printed circuit board (PCB);

FIG. 4 illustrates a single-side PCB according to an exemplary embodiment;

FIG. 5 is a cross-section view of the single-sided PCB according to an exemplary embodiment;

FIG. 6 illustrates that a textile fiber material and a resin material are respectively applied to an upper layer and a lower layer of the PCB mounted with parts according to an exemplary embodiment;

FIG. 7 is a cross-section view of a double-sided PCB according to an exemplary embodiment;

FIG. 8 is a cross-section view of a multi-layered PCB according to an exemplary embodiment;

FIG. 9 is a flowchart of manufacturing the PCB of a CEM-1 material according to an exemplary embodiment;

FIG. 10 is a flowchart of manufacturing the single-sided PCB according to an exemplary embodiment;

FIG. 11 is a flowchart of manufacturing the multi-layered PCB according to an exemplary embodiment;

FIG. 12 illustrates that a textile fiber material and a resin material are respectively applied to an upper layer and a lower layer of the single-sided PCB according to an exemplary embodiment;

FIG. 13 illustrates that a textile fiber material and a resin material are respectively applied to an upper layer and a lower layer of the double-sided PCB according to an exemplary embodiment; and

FIG. 14 illustrates that a textile fiber material and a resin material are respectively applied to an upper layer and a lower layer among a plurality of layers of the multi-layered PCB according to an exemplary embodiment.

### DETAILED DESCRIPTION OF EXEMPLARY EMBODIMENTS

Below, exemplary embodiments will be described in detail with reference to accompanying drawings so that they can be easily realized by a person having an ordinary skill in the art. The exemplary embodiments may be achieved in various forms and not limited to the following embodiments. For convenience of description, parts not directly related to the exemplary embodiments are omitted, and like numerals refer to like elements throughout.

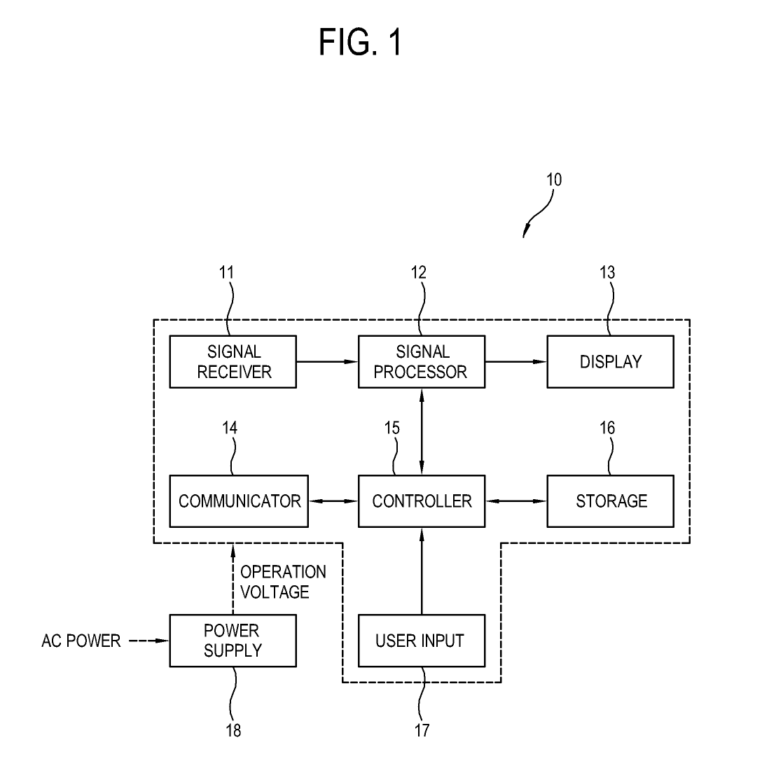

FIG. 1 is a block diagram of a display apparatus according to an exemplary embodiment. As shown in FIG. 1, the display apparatus 10 according to an exemplary embodiment includes a signal receiver 11, a signal processor 12, a display 13, a communicator 14, a controller 15, a storage 16, a user input 17 and a power supply 18, and may be for example achieved by a TV, an audio system, a tablet computer, a personal computer, a notebook computer, etc. The elements involved in the electronic device 10 according to this exemplary embodiment are not limited to the foregoing description, and may further include additional elements.

The signal receiver 11 receives a broadcast signal. The signal receiver 11 may be variously achieved in accordance with the formats of the broadcast signal to be received and the types of the display apparatus 10. For example, the signal receiver 11 may be achieved by a tuner that receives a radio frequency (RF) broadcast signal or satellite signal from a broadcasting station. Alternatively, the signal receiver 11 may receive a video signal from a video device connected to the display apparatus 10, for example, a digital versatile disc (DVD) player, a Blu-ray disc (BD) player or the like. In addition, the signal receiver 11 may receive an audio signal for outputting sound, a data signal for outputting data information, etc. as well as the video signal. In this case, the video signal, the audio signal and the data signal may be received as a single signal. Thus, the signal receiver 11 is not limited to this exemplary embodiment and may be achieved variously to receive a broadcast signal.

The signal processor 12 performs a plurality of signal processes with regard to an image signal received in the signal receiver 11. The signal process includes decoding, de-interlacing, scaling, noise reduction, detail enhancement, etc. but not limited thereto. The signal processor 12 may be achieved by a system-on-chip (SOC) where various functions are integrated, or image processing boards where individual elements for independently performing the respective processes are mounted. Further, the signal processor 12 may process the audio signal and the data signal received in the signal receiver 11.

The display 13 displays an image based on an image signal processed by the signal processor 12. The display 13 may be achieved by various types. For example, the display 13 may be achieved by a plasma display panel (PDP), a liquid crystal display (LCD), an organic light emitting diode (OLED), a flexible display, etc.

The communicator 14 communicates with an external device (not shown) through Internet or the like network. Further, the communicator 14 may communicate with the external device through Bluetooth, wireless fidelity (Wi-Fi), etc. Under control of the controller 15, the communicator 14 performs communication to transmit information to the external device or receive information from the external device. The information received from the external device through the communicator 14 may include video information, audio information and data information, and undergoes corresponding processes to be output to the display 13 or the like.

The user input 17 receives a user's input. For example, the user input 17 may be achieved by a keyboard, a mouse, etc. or by an input panel provided on the outside of the display apparatus 10. According to an exemplary embodiment, the user input 17 may receive a user's input through a remote controller. A user's input may include at least one of selection of a menu, input of a shortcut key, voice, motion, etc. The user's input received in the user input 17 is transmitted to the controller 15 so that operations corresponding to the user's input can be implemented.

The storage 16 is an element provided in the display apparatus 10 and storing data and information. For example, the storage 16 may be achieved by a hard disk drive, a flash memory, or the like nonvolatile memory.

The controller 15 generally controls the elements of the display apparatus 10. The controller 15 may include firmware as a control program, and a central processing unit (CPU) and a random access memory (RAM) for executing the firmware.

The power supply 18 receives alternating current (AC) power and supplies power to the display 13 and the like elements of the display apparatus 10. The power supply 18 transforms the received AC power into power having levels needed for the display 13 and the like elements.

According to an exemplary embodiment, the display apparatus 10 includes a printed circuit board mounted with the power supply 18 that receives an AC power signal and supplies the operation power to the display 13. The printed circuit board includes a base layer having a plurality of paper layers; a waterproof insulation layer made of a textile fiber material and laid on a first surface of the base layer; a copper foil layer laid on a second surface opposite to the first surface of the base layer and printed with a signal line pattern to be connectable to at least one circuit device included in the power supply 18 on an opposite surface to a surface facing the second surface of the base layer; and a waterproof adhesive layer interposed between the base layer and the copper foil layer and containing an adhesive material for adhesion between the base layer and the copper foil layer.

Thus, the printed circuit board included in the display apparatus 10 according to an exemplary embodiment has the waterproof insulation layer of the textile fiber material on an upper layer of a substrate, and the waterproof adhesive layer of a resin material on a lower layer of the substrate to adhere to the copper foil, thereby blocking moisture from the outside. Further, the waterproof adhesive layer to adhere to the copper foil is made of not the textile fiber material but the resin material, which reduces manufacturing costs of the printed circuit board.

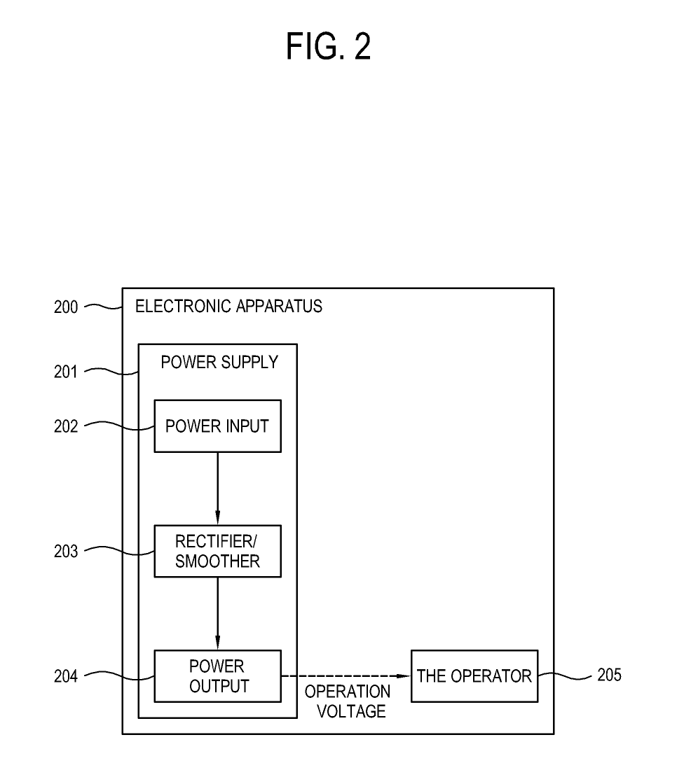

FIG. 2 is a block diagram of an electronic apparatus according to an exemplary embodiment. As shown in FIG. 2, an electronic apparatus 200 includes a power supply 201, and an operator that receives operating power output from the power supply 201. The power supply 201 includes a power input 202, a rectifier/smoother 203, and a power output 204, and the electronic apparatus 200 includes a substrate (not shown) provided with these elements. For example, the electronic apparatus 200 may be a set-top box, a car dashboard, etc. The electronic apparatus 200 may be a display apparatus.

The power input 202 receives AC power and filters an input current.

The rectifier/smoother 203 rectifies and smooths the AC power filtered by the power input 202 and outputs the rectified and smoothed power. The rectifier/smoother 203 rectifies the filtered current to thereby convert AC into direct current (DC). The rectifier/smoother 203 may include a bridge diode to rectify the current.

The rectifier/smoother 203 may include a smoothing capacitor for smoothing DC voltage output by rectifying the filtered current. The rectifier/smoother 203 boosts the voltage charged in the smoothing capacitor to thereby improved power factor of the power supply 201.

The power output 204 transforms a level of voltage output from the rectifier/smoother 203 and outputs it as an operation power to the operator 205. The operator 205 receives the operation power output from the power output 204 and performs at least one function among a plurality of functions that can be implemented in the electronic apparatus 200.

The substrate (not shown) is provided with the power supply 201 that receives an AC power signal and supplies the operation power to the electronic apparatus 200. That is, the substrate is mounted with circuit elements corresponding to the power input 202, the rectifier/smoother 203 and the power output 204 included in the power supply 201.

The substrate may be made of a CEM-1 material. For example, the substrate may be achieved by applying woven glass fiber impregnated with epoxy resin to one side of a paper core impregnated with epoxy resin. The substrate may be for example achieved by a single-sided PCB, a double-sided PCB, a multi-layered PCB, etc. However, there are no limits to the kinds of substrate, and various kinds of PCB may be employed for the substrate.

The substrate includes a base layer having a plurality of paper layers; a waterproof insulation layer laid on a first surface of the base layer; a copper foil layer laid on a second surface opposite to the first surface of the base layer and printed with a signal line pattern to be connectable to at least one circuit device included in the power supply 201 on an opposite surface to a surface facing the second surface of the base layer; and a waterproof adhesive layer interposed between the base layer and the copper foil layer and containing an adhesive material for adhesion between the base layer and the copper foil layer.

According to an exemplary embodiment, the waterproof insulation layer may include the textile fiber material, and the waterproof adhesive layer may include a semi-hardening epoxy resin material as the adhesive material. Further, the waterproof adhesive layer may further include insulating resin as the waterproof material. The waterproof adhesive layer may be formed as a single layer by combining the adhesive material and the waterproof material. Further, the waterproof adhesive layer may be hardened by heating at high temperature and used for adhesion between the base layer and the copper foil layer.

According to an exemplary embodiment, the waterproof insulation layer and the waterproof adhesive layer may include the insulating material to make a comparative tracking index (CTI) be equal to or higher than a predetermined value. The CTI refers to resistance to voltage under contaminated circumstances. The CTI is expressed as voltages causing the tracking, which are measured after a total of about 50 drops of electrolyte (e.g. 0.1 percent ammonium chloride solution) have fallen on the substrate by one drop every 30 seconds. The higher the CTI is, the better the insulating properties are under the contaminated circumstances. The CTI is categorized according to measured voltages, as categories such as ‘5’, ‘4’, ‘3’, ‘2’, ‘1’ and ‘0’ respectively corresponding to a voltage lower than 100V, a voltage equal to or higher than 100V but lower than 175V, a voltage equal to or higher than 175V but lower than 250V, a voltage equal to or higher than 250V but lower than 400V, a voltage equal to or higher than 400V but lower than 600V, a voltage equal to or higher than 600V. In the printed circuit board according to an exemplary embodiment, the waterproof insulation layer used for the upper layer and the waterproof adhesive layer used for the lower layer may respectively include the textile fiber material and the resin material as the insulating materials having the CTI equal to or higher than 600V.

In this exemplary embodiment, the electronic apparatus 200 employs the waterproof insulation layer of the textile fiber material as the upper layer of the substrate, and employs the waterproof adhesive layer of the resin material as the lower layer of the substrate to adhere to the copper foil, thereby blocking moisture from the outside. Further, the waterproof adhesive layer to adhere to the copper foil is made of not the textile fiber material but the resin material, which reduces manufacturing costs of the substrate.

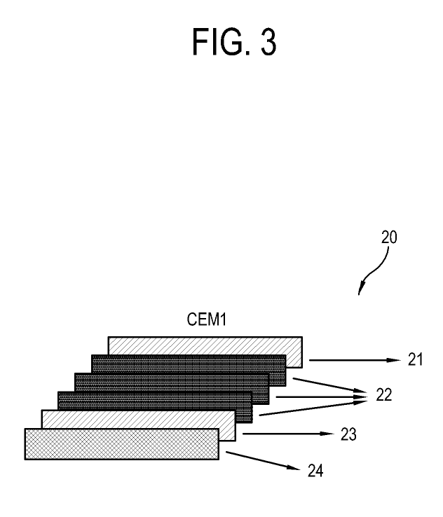

FIG. 3 illustrates a conventional single-side printed circuit board (PCB). As shown in FIG. 3, a single-sided PCB 20 is a PCB made of a CEM-1 material, which has a structure where a first textile fiber layer 21 is laid at an upper side of a paper layer 22 including a plurality of paper layers, and a second textile fiber layer 23 is laid at a lower side of the paper layer 22 and adheres to the copper foil layer 24. At this time, the paper layer 22 may be achieved by a paper core impregnated with epoxy resin. Further, the first textile fiber layer 21 and the second textile fiber layer 23 may be achieved by the insulation layers including glass fiber impregnated with epoxy resin.

Such a conventional single-sided PCB 20 has an effect of blocking moisture from the outside since the first textile fiber layer 21 and the second textile fiber layer 23 are used at both sides of the paper layer 22. However, if the single-sided PCB 20 has to be mass produced, to the cost of the glass fiber for the first textile fiber layer 21 and the second textile fiber layer 23 is high.

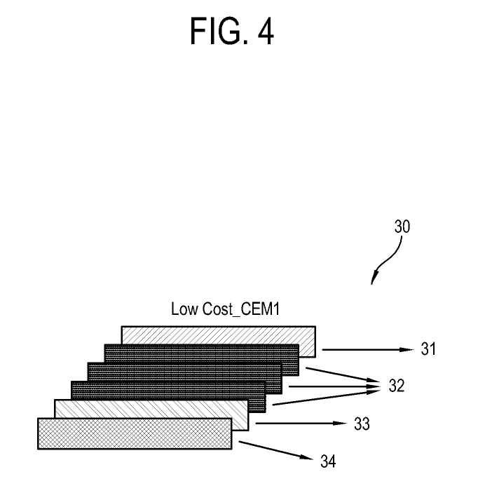

FIG. 4 illustrates a single-side PCB according to an exemplary embodiment. To overcome shortcomings of the conventional single-sided PCB 20 of FIG. 3, the single-sided PCB 30 as shown in FIG. 4 includes a waterproof insulation layer 31, a base layer 32, a waterproof adhesive layer 33 and a copper foil layer 34, which are laid in sequence from an upper side of a substrate. The single-sided PCB 30 may be achieved by a PCB made of a CEM-1 material. For example, the single-sided PCB 30 may be achieved by applying woven glass fiber impregnated with epoxy resin to one side of a paper core impregnated with epoxy resin.

The base layer 32 includes a plurality of paper layers. The base layer 32 may include an epoxy resin material. For example, the base layer 32 may be achieved by a paper core in which a plurality of paper layers is impregnated with epoxy resin.

The waterproof insulation layer 31 is laid on an upper surface of the base layer 32. The waterproof insulation layer 31 may contain the textile fiber material. For example, the waterproof insulation layer 31 may be achieved by the glass fiber impregnated with epoxy resin. Further, the waterproof insulation layer 31 may include an insulating material to have a CTI equal to or higher than a predetermined value. The CTI is expressed as a voltage causing the tracking, which is measured after a total of about 50 drops of electrolyte (e.g. 0.1 percent ammonium chloride solution) have fallen on the substrate by one drop every 30 seconds. The higher the CTI is, the better the insulating properties are under the contaminated circumstances. For example, the waterproof insulation layer 31 may include the textile fiber material as the insulating material so as to have a CTI equal to or higher than 600V.

In this manner, the single-sided PCB 30 employs the waterproof insulation layer 31 of the textile fiber material on the upper side of the base layer 32, thereby blocking moisture introduced from the upper side.

The copper foil layer 34 is laid on a lower surface of the base layer 32, and is printed with a signal line pattern to be connectable to at least one circuit device on an opposite surface to a surface facing the lower surface of the base layer 32. The copper foil layer 34 may be achieved by a thin plate coated with copper (Cu).

The waterproof adhesive layer 33 is interposed between the base layer 32 and the copper foil layer 34 and contains an adhesive material for adhesion between the base layer 32 and the copper foil layer 34. The waterproof adhesive layer 33 may include a semi-hardening epoxy resin material as the adhesive material. The waterproof adhesive layer 33 may further include a waterproof material. The waterproof adhesive layer 33 may include an insulating resin material as the waterproof material. The waterproof adhesive layer 33 may be formed as a single layer by combining the adhesive material and the waterproof material. For example, the waterproof adhesive layer 33 employs the semi-hardening epoxy resin material having adhesive and insulating properties, thereby not only making the base layer 32 and the copper foil layer 34 adhere to each other but also blocking moisture from the outside. Alternatively, the waterproof adhesive layer 33 may contain at least one of polyester resin and thermoplastic resin in addition to the semi-hardening epoxy resin material to thereby not only make the base layer 32 and the copper foil layer 34 adhere to each other but also block off moisture from the outside.

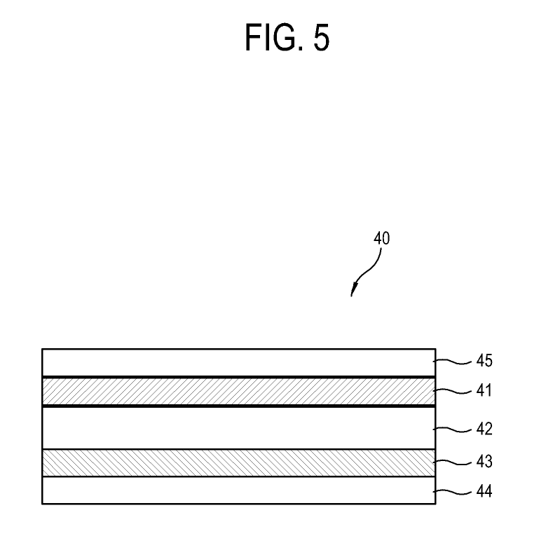

FIG. 5 is a cross-sectional view of the single-sided PCB according to an exemplary embodiment. As shown in FIG. 5, the single-sided PCB 40 includes a part layer 45, a waterproof insulation layer 41, a base layer 42, a waterproof adhesive layer 43 and a copper foil layer 44, which are laid in sequence from an upper side of a substrate. Here, the waterproof insulation layer 41, the base layer 42, the waterproof adhesive layer 43 and the copper foil layer 44 of FIG. 5 are respectively equivalent to the waterproof insulation layer 31, the base layer 32, the waterproof adhesive layer 33 and the copper foil layer 34 of FIG. 4, and thus repetitive descriptions thereof will be avoided as necessary.

The single-sided PCB 40 may be achieved by a PCB made of a CEM-1 material. For example, the single-sided PCB 40 may be achieved by applying woven glass fiber impregnated with epoxy resin to one side of a paper core impregnated with the epoxy resin.

The base layer 42 may include a plurality of paper layers impregnated with the epoxy resin. The waterproof insulation layer 41 may contain a textile fiber material impregnated with the epoxy resin. The copper foil layer 44 may be achieved by a thin plate coated with copper (Cu).

The waterproof adhesive layer 43 may be interposed in between the base layer 42 and the copper foil layer 44, and may contain a semi-hardening epoxy resin material for not only adhesion between the base layer 42 and the copper foil layer 44 but also for waterproofing. The waterproof adhesive layer 43 may contain at least one among epoxy resin, polyester resin and thermoplastic resin as the insulating resin material.

When the single-sided PCB 40 is manufactured, the waterproof insulation layer 41, the base layer 42 and the waterproof adhesive layer 43 may form a ‘Prepreg’ as they are dried and semi-hardened after being impregnated with their respective resin materials. Then, the Prepregs of the waterproof insulation layer 41, the base layer 42 and the waterproof adhesive layer 43 and the copper foil layer 44 are laid in sequence and subjected to high temperature and high pressure, so that the Prepregs can be changed from a semi-hardened state to a hardened state. For example, in case of the Prepreg of the epoxy resin material, the semi-hardened state can be turned into the hardened state by heating the Prepreg at a temperature of 175 to 185 degrees for 90 to 120 minutes under a pressure of 20˜40 kgf/cm². Alternatively, in case of Prepregs of resin materials other than the epoxy resin material, their hardening characteristics are different in accordance with the kinds of resin, and therefore the Prepregs are subject to hardening conditions specified by sufficient preliminary tests.

Thus, the single-sided PCB 40 may form a single copper foil laminated plate where the waterproof insulation layer 41, the base layer 42 and the waterproof adhesive layer 43 and the copper foil layer 44 are stuck together.

In the single-sided PCB 40, the part layer 45 mounted with parts is formed on the upper side of the copper foil laminated plate formed as described above, and the parts are connected through a through hole (not shown), thereby forming a circuit on the copper foil layer 44. Further, the single-sided PCB 40 is manufactured as an end product by processes of etching copper foil, removing resist, machining an outer appearance, etc.

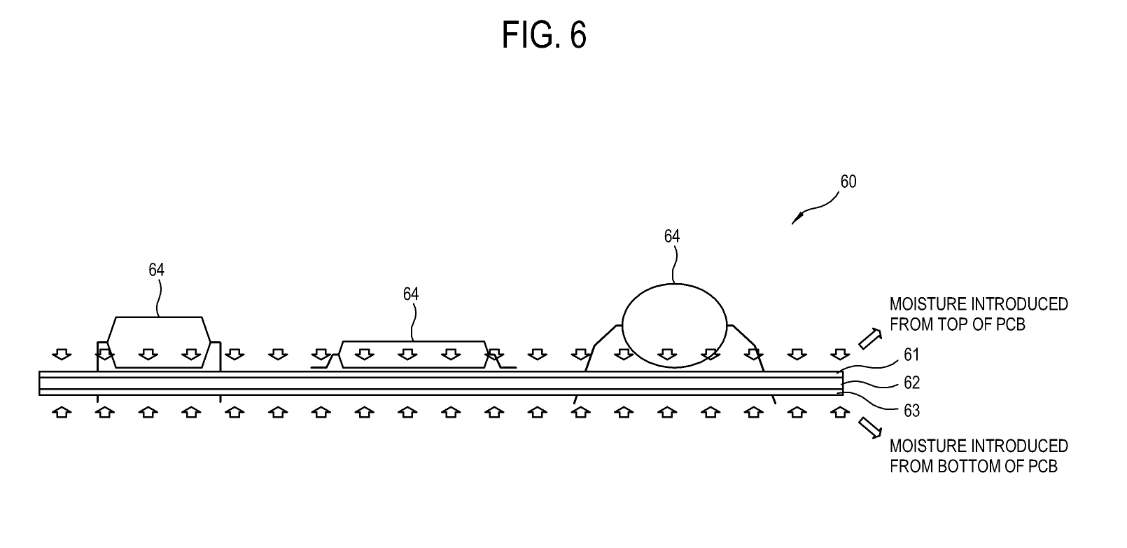

FIG. 6 illustrates that a textile fiber material and a resin material are respectively applied to an upper layer and a lower layer of the PCB mounted with parts according to an exemplary embodiment. As shown in FIG. 6, a single-sided PCB 60 includes a base layer 62, a waterproof insulation layer laid on an upper surface of the base layer 62, and a waterproof adhesive layer 63 laid on a lower surface of the base layer 62. The single-sided PCB 60 may be achieved by a PCB made of a CEM-1 material. The single-sided PCB 60 may include a plurality of parts 64 mounted onto the upper side of the waterproof insulation layer 61, and the plurality of parts may include a transformer for supplying power, a photo coupler, a Y-capacitor, etc. Alternatively, the plurality of parts 64 to be mounted may include a power input. In the single-sided PCB 60, a copper foil layer (not shown) made of copper is provided on the lower side of the waterproof adhesive layer 63, and formed with a circuit pattern on which the plurality of parts 64 are connected via a through hole (not shown).

The base layer 62 may include a paper core and epoxy resin, and the waterproof insulation layer 61 may include the textile fiber material and the epoxy resin. The waterproof adhesive layer 63 is an element for sticking the base layer 62 to the copper foil layer (not shown), and may for example include a semi-hardening epoxy resin material for both adhesion and waterproofing. Alternatively, the waterproof adhesive layer 63 may further include at least one of polyester resin and thermoplastic resin in addition to the epoxy resin material so as to have the adhesive and waterproof functions. Further, the waterproof adhesive layer 63 is not limited to this embodiment, and may include another material for the adhesive and waterproof functions instead of the resin material.

Like this, the single-sided PCB 60 employs the waterproof insulation layer 61 of the textile fiber material to the upper side of the substrate, and employs the waterproof adhesive layer 63 of the epoxy resin material to the lower side of the substrate, thereby blocking moisture introduced from the upper side and the lower side of the substrate.

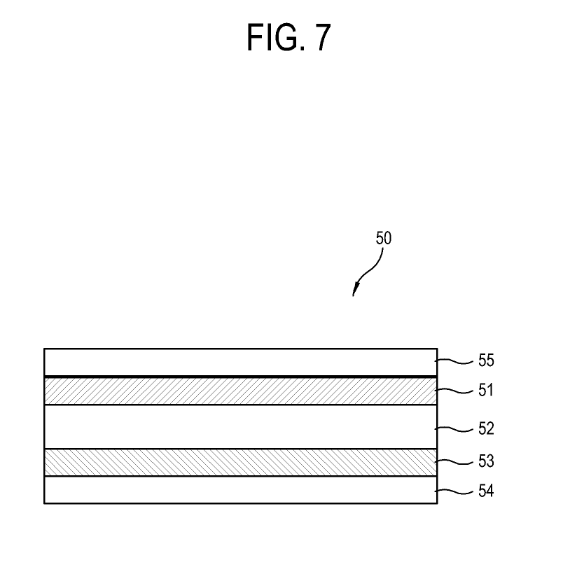

FIG. 7 is a cross-sectional view of a double-sided PCB according to an exemplary embodiment. As shown in FIG. 7, the double-sided PCB 50 includes a copper foil layer 55, a waterproof insulation layer 51, a base layer 52, a waterproof adhesive layer 53 and a copper foil layer 54, which are laid in sequence from the upper side of the substrate to the lower side. The double-sided PCB 50 may be achieved by a PCB made of a CEM-1 material. For example, the double-sided PCB 50 may be achieved by applying woven glass fiber impregnated with epoxy resin to one side of a paper core impregnated with the epoxy resin.

The base layer 52 may include a plurality of paper layers impregnated with the epoxy resin. The waterproof insulation layer 51 may contain a textile fiber material impregnated with the epoxy resin. The copper foil layer 54 may be achieved by a thin plate coated with copper (Cu).

The waterproof adhesive layer 53 is interposed between the base layer 52 and the copper foil layer 54, and may contain a semi-hardening epoxy resin material for adhesion between the base layer 52 and the copper foil layer 54 and waterproofing. The waterproof adhesive layer 53 may further include at least one among the epoxy resin, polyester resin and thermoplastic resin as the insulating resin material.

When the double-sided PCB 50 is manufactured, the waterproof insulation layer 51, the base layer 52 and the waterproof adhesive layer 53 may form a ‘Prepreg’ as they are dried and semi-hardened after being impregnated with their respective resin materials. The Prepregs of the waterproof insulation layer 51, the base layer 52, the waterproof adhesive layer 53, the copper foil layer 44 at the upper side and the copper foil layer 54 of the lower side are laid in sequence and subjected to high temperature and high pressure, so that the Prepregs can be changed from a semi-hardened state to a hardened state. For example, in case of the Prepreg of the epoxy resin material, a semi-hardened Prepreg can be turned into a hardened Prepreg by heating the Prepreg at a temperature of 175 to 185 degrees for 90 to 120 minutes under a pressure of 20˜40 kgf/cm². Alternatively, in case of Prepregs of resin materials other than the epoxy resin material, their hardening characteristics are different in accordance with the kinds of resin, and therefore the Prepregs are subject to hardening conditions specified by sufficient preliminary tests.

Thus, the double-sided PCB 50 may form a single copper foil laminated plate where the waterproof insulation layer 51, the base layer 52, the waterproof adhesive layer 53 and the copper foil layers 54 and 55 are stuck together.

In the double-sided PCB 50, circuit patterns, in which mounted parts are connected via a through hole (not shown), are respectively printed on the copper foil layer 55 at the upper side and the copper foil layer 54 at the lower side of the copper foil laminated plate formed as described above. Further, the double-sided PCB 50 is manufactured as an end product by processes of etching copper foil removing resist, machining an outer appearance, etc. at the upper side and the lower side.

With this structure, the double-sided PCB 50 employs the textile fiber material to the upper side of the substrate, and employs the epoxy resin material to the lower side of the substrate, thereby blocking moisture that may be introduced from the upper and lower sides of the substrate. Further, it is possible to reduce the manufacturing costs of the substrate since the double-sided PCB 50 employs only the epoxy resin material instead of the textile fiber material for the lower side of the substrate.

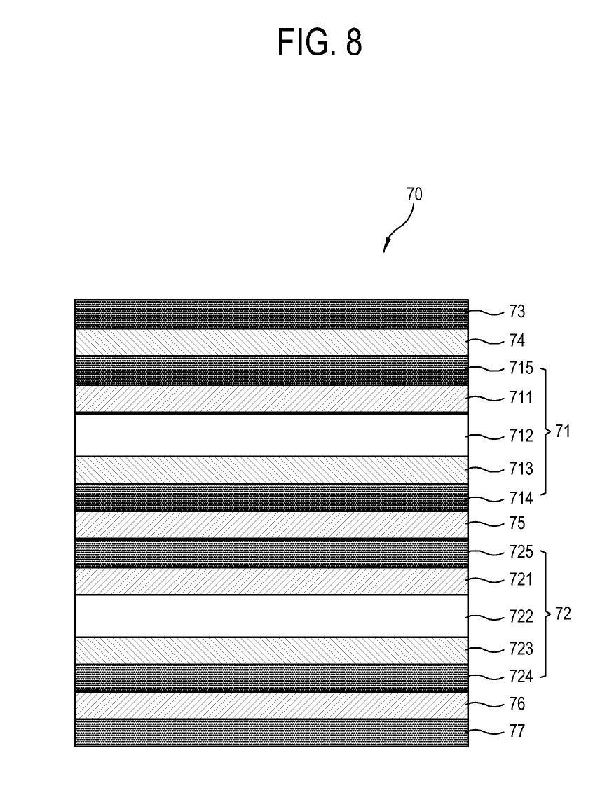

FIG. 8 is a cross-sectional view of a multi-layered PCB according to an exemplary embodiment. As shown in FIG. 8, a multi-layered PCB 70 may be achieved by sticking together two or more double-sided PCB 60 of FIG. 7. According to an exemplary embodiment, the multi-layered PCB 70 may include a first copper foil laminated plate 71 which includes a first copper foil layer 715, a first waterproof insulation layer 711, a first base layer 712, a first waterproof adhesive layer 713 and a second copper foil layer 714, and a second copper foil laminated plate 72 which includes a third copper foil layer 725, a second waterproof insulation layer 721, a second base layer 722, a second waterproof adhesive layer 723 and a fourth copper foil layer 724, and an adhesive layer 75 which is interposed in between the first copper foil laminated plate 71 and the second copper foil laminated plate 72. Further, the multi-layered PCB 70 may include an adhesive layer 74 and an upper side copper foil layer 73 on the upper side of the first copper foil laminated plate 71, and an adhesive layer 76 and a lower side copper foil layer 77 on the lower side of the second copper foil laminated plate 72.

The first copper foil laminated plate 71 may be formed by sticking the first waterproof insulation layer 711 of the textile fiber material for adhering to the first copper foil layer 715 to the upper side of the first base layer 712 having a plurality of paper layers of an epoxy resin material, and sticking the first waterproof adhesive layer 713 of the epoxy resin material for adhering to the second copper layer 714 to the lower side of the first base layer 712.

Similarly, the second copper foil laminated plate 72 may be formed by sticking the second waterproof insulation layer 721 of the textile fiber material for adhering to the third copper foil layer 725 to the upper side of the second base layer 722 having the plurality of paper layers of the epoxy resin material, and sticking the second waterproof adhesive layer 723 of the epoxy resin material for adhering the fourth copper foil layer 724 to the lower side of the second base layer 722.

In this manner, the multi-layered PCB 70 includes the first copper foil laminated plate 71 and the second copper foil laminated plate 72, which are each achieved by the double-sided PCB made of the CEM-1 material, and the adhesive layers 74, 75, and 76, which are interposed between the first copper foil laminated plate 71 and the second copper foil laminated plate 72, between the upper side copper foil layer 73 at the upper side and the first copper foil laminated plate 71, and between the second copper foil laminated plate 72 and the lower side copper foil layer 77 at the lower side.

The adhesive layers 75, 74 and 77 may be achieved by Prepregs of semi-hardened epoxy resin materials. The Prepregs of the adhesive layers 74, 75, and 77 are subjected to high temperature and high pressure and thus changed from a semi-hardened state to a hardened state. For example, in case of the Prepreg of the epoxy resin material, a semi-hardened Prepreg can be turned into a hardened Prepreg by heating the Prepreg at a temperature of 175 to 185 degrees for 90 to 120 minutes under a pressure of 20˜40 kgf/cm².

In the multi-layered PCB 70, the upper side copper foil layer 73 and the lower side copper foil layer 77 may be formed with an outer layer circuit to be connected to mounted parts via through holes (not shown). Additionally, the multi-layered PCB 70 may include an inner layer circuit formed in copper foil of the first copper foil laminated plate 71 and the second copper foil laminated plate 72 and connected to the outer layer circuit through the VIA holes (not shown).

In the multi-layered PCB 70 with this structure including the plurality of copper foil laminated plates, the textile fiber material is used at the upper side of each copper foil laminated plate and the epoxy resin material is used at the lower side, thereby blocking moisture from the outside. Further, it is possible to reduce manufacturing costs of the multi-layered PCB 70 because instead of the textile fiber material, the epoxy resin material is used at each lower side of the plurality of copper foil laminated plates.

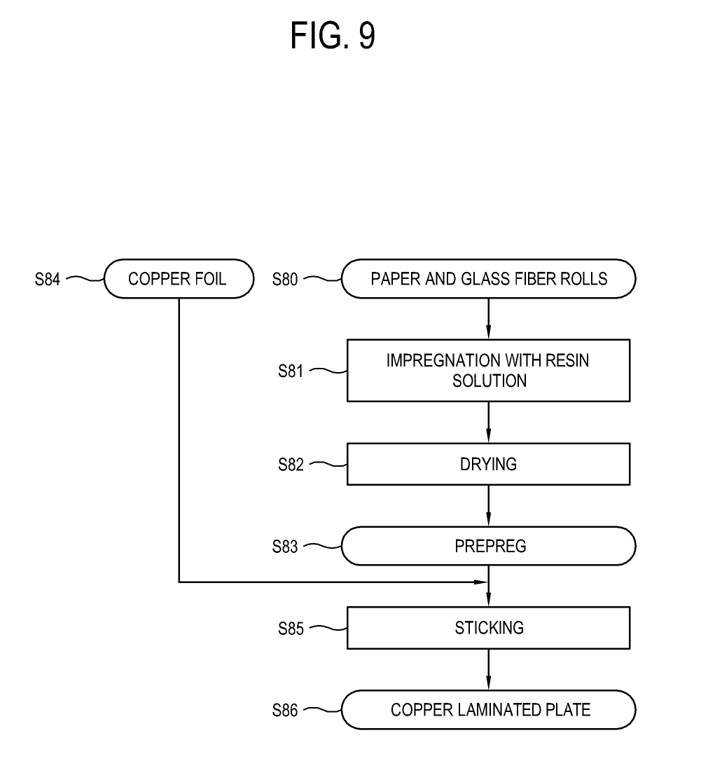

FIG. 9 is a flowchart of manufacturing the PCB of a CEM-1 material according to an exemplary embodiment. As shown in FIG. 9, at operation S80, paper and glass fiber rolls are prepared. At operation S81, paper and glass fiber rolls are impregnated with resin solution. The resin solution may be, for example, epoxy resin. Next, at operation S82, the paper and glass fiber impregnated with the epoxy resin are dried. At operation S83, Prepregs of the paper and glass fiber are formed.

Next, at operation S84, copper foil is formed. At operation S85, the Prepregs of the paper and glass fiber and the copper foil are stuck together. At this time, the glass fiber Prepreg is applied to the upper side of the paper Prepreg, and the waterproof adhesive layer is applied to the lower side of the paper Prepreg so as to adhere to the copper foil. The waterproof adhesive layer may contain the semi-hardening epoxy resin material for adhesion, and the insulating resin material for waterproofing. Lastly, at operation S86, the laminated layers are subjected to high temperature and high pressure, thereby generating the copper foil laminated plate of a PCB where the respective layers are stuck together.

The copper foil laminated plate according to an exemplary embodiment may include the glass fiber at the upper side, and the adhesive layer of the resin material for adhering to the copper foil at the lower side, thereby blocking moisture and reducing manufacturing costs.

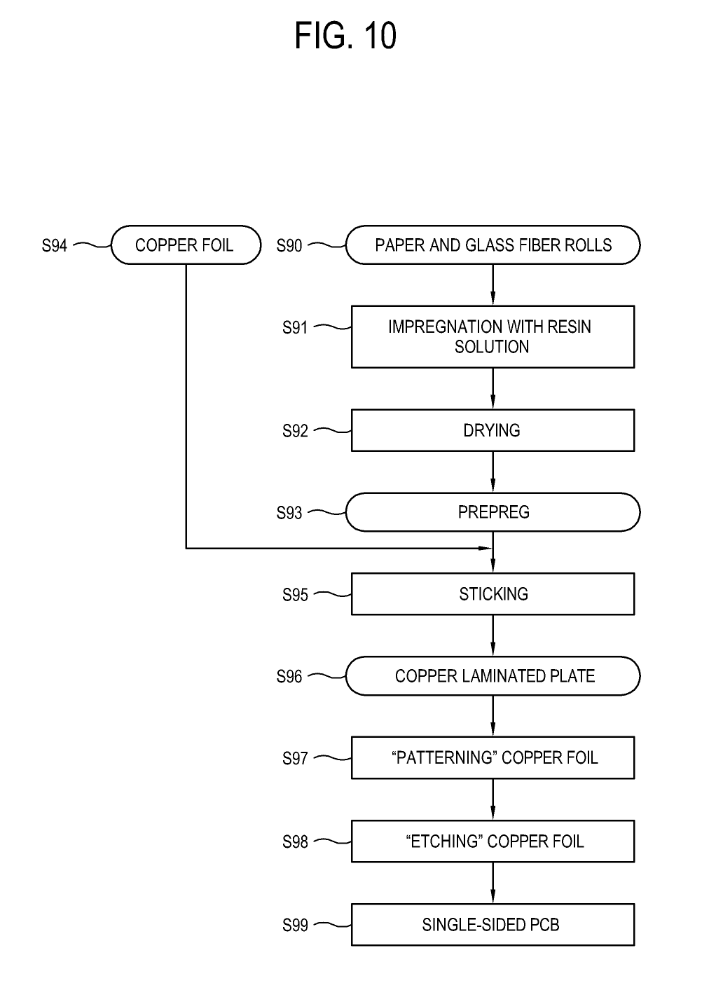

FIG. 10 is a flowchart of manufacturing the single-sided PCB according to an exemplary embodiment. As shown in FIG. 10, at operation S90, paper and glass fiber rolls are prepared. At operation S91, the paper and glass fiber rolls are impregnated with the resin solution. The resin solution may be, for example, the epoxy resin. Next, at operation S92, the paper and glass fiber impregnated with the epoxy resin are dried. At operation S93, Prepregs of the paper and glass fiber are formed.

Next, at operation S94, the copper foil is formed. At operation S95, the Prepregs of the paper and glass fiber and the copper foil are stuck together. At this time, the glass fiber Prepreg is applied to the upper side of the paper Prepreg, and the waterproof adhesive layer is applied to the lower side of the paper Prepreg so as to adhere to the copper foil. The waterproof adhesive layer may contain a semi-hardening epoxy resin material for adhesion, and an insulating resin material for waterproofing.

Next, at operation S96 the laminated layers are subjected to high temperature and high pressure, thereby generating the copper foil laminated plate of a PCB where the respective layers are stuck together. At operation S97, the copper foil of the copper foil laminated plate is patterned. At operation S98, the copper foil is etched. At operation S99, the single-sided PCB is formed.

According to an exemplary embodiment, the operations S90 to S98 are not limited to the manufacturing process of the single-sided PCB, and may be applied to the manufacturing process of the double-sided PCB.

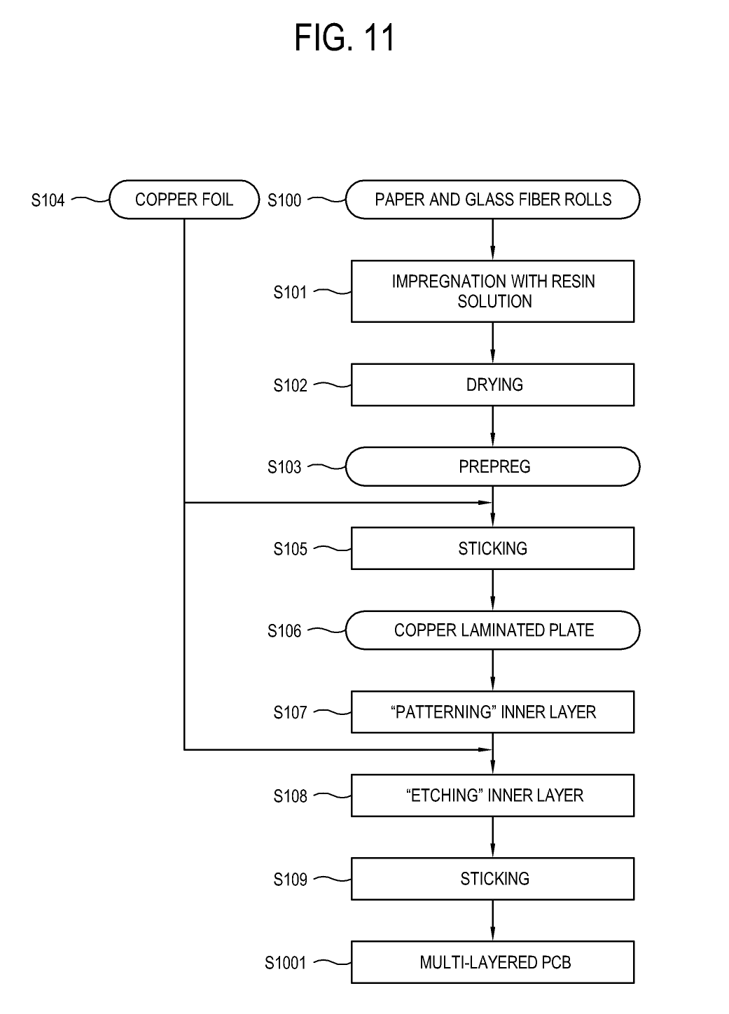

FIG. 11 is a flowchart of manufacturing the multi-layered PCB according to an exemplary embodiment. As shown in FIG. 11, at operation S100, paper and glass fiber rolls are prepared. At operation S101, the paper and glass fiber rolls are impregnated with resin solution. The resin solution may be for example epoxy resin. Next, at operation S102, the paper and glass fiber impregnated with the epoxy resin are dried. At operation S103, Prepregs of the paper and glass fiber are formed.

Next, at operation S104, copper foil is formed. At operation S105, the Prepregs of the paper and glass fiber and the copper foil are stuck together. At this time, the glass fiber Prepreg is applied to the upper side of the paper Prepreg, and the waterproof adhesive layer is applied to the lower side of the paper Prepreg so as to adhere to the copper foil. The waterproof adhesive layer may contain a semi-hardening epoxy resin material for adhesion, and an insulating resin material for waterproofing.

Next, at operation S106, the laminated layers are subjected to high temperature and high pressure, thereby forming the copper foil laminated plate of a PCB where the respective layers are stuck together. At operation S107, the inner layer of the copper foil laminated plate is patterned. At operation S108, the inner layer is etched. At operation S109, the plurality of copper foil laminated plates are stuck together, and the upper and lower sides thereof are formed with the copper foil. At this time, the adhesive layer of the epoxy resin material is applied between the plurality of copper foil laminated plates. At operation S1001, the multi-layered PCB where the plurality of copper foil laminated plates are stuck together is formed by high temperature and high pressure.

In the multi-layered PCB according to this exemplary embodiment, when the plurality of copper foil laminated plates to be stuck together are manufactured, the textile fiber material is used at the upper side, and the adhesive material of the epoxy resin is used at the lower side, thereby having effects on blocking moisture from the outside while reducing costs.

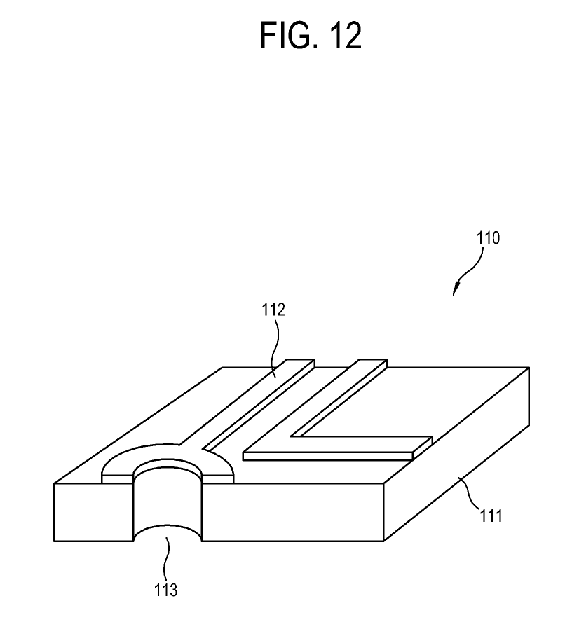

FIG. 12 illustrates that a textile fiber material and a resin material are respectively applied to an upper layer and a lower layer of the single-sided PCB according to an exemplary embodiment. As shown in FIG. 12, a single-sided PCB 110 has low mounting density and is simply manufactured since a circuit is formed at only one side. The single-sided PCB 110 may be for example used for a TV, a video tape recorder (VTR), an audio system, etc. The single-sided PCB 110 may be made of the CEM-1 material containing the textile fiber. The single-sided PCB 110 includes an insulation layer 111, a copper foil layer printed with a single-sided circuit pattern 112, and a through hole 113 through which parts are mounted.

According to an exemplary embodiment, the insulation layer 111 of the single-sided PCB 110 may include a base layer having a plurality of paper layers impregnated with epoxy resin, a waterproof insulation layer made of a textile fiber material and laid on one side of the base layer, and a waterproof adhesive layer interposed between the base layer and the copper foil layer and made of an epoxy resin material for adhesion between the base layer and the copper foil layer. At this time, the waterproof adhesive layer may further include the resin material for waterproofing.

Thus, the single-sided PCB 110 employs the textile fiber material on one side of the insulation layer 111 and employs the waterproof adhesive layer of the resin material on the other side for adhering to the copper foil layer, thereby blocking moisture from the outside.

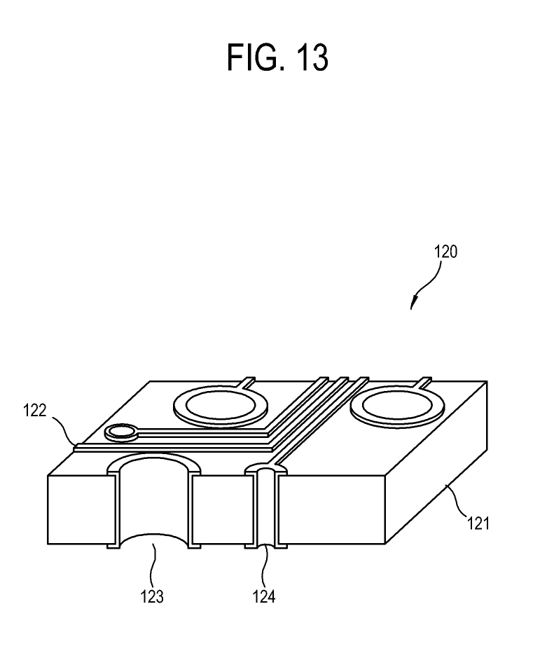

FIG. 13 illustrates that a textile fiber material and a resin material are respectively applied to an upper layer and a lower layer of the double-sided PCB according to an exemplary embodiment. As shown in FIG. 13, a double-sided PCB 120 is formed with circuits on top and bottom sides thereof, i.e. double-sides. The double-sided PCB 120 has higher mounting density than that of the single-sided PCB 110 shown in FIG. 12. The double-sided PCB 120 may be for example applied to a printer, facsimiles, and the like low-function office automation (OA) device and inexpensive industrial device. The double-sided PCB 120 may be made of a CEM-1 material containing textile fiber.

The double-sided PCB 120 includes an insulation layer 121, a copper foil layer printed with a top circuit pattern 122, and a through hole 123 through which parts are mounted by connecting the top circuit pattern 122 and a bottom circuit patterned on an opposite side. Further, the double-sided PCB 120 may include a VIA hole 124 through which the top circuit pattern 122 and the bottom circuit pattern are connected.

According to an exemplary embodiment, the insulation layer 121 of the double-sided PCB 120 may include a base layer having a plurality of paper layers impregnated with epoxy resin, a waterproof insulation layer made of a textile fiber material and laid on one side of the base layer, and a waterproof adhesive layer interposed between the base layer and the copper foil layer and made of an epoxy resin material for adhesion between the base layer and the copper foil layer. The waterproof adhesive layer may further include the resin material for waterproofing. The waterproof insulation layer may further include the epoxy resin material.

Thus, the double-sided PCB 120 employs the textile fiber material on one side of the insulation layer 121 and employs the waterproof adhesive layer of the resin material on the other side for adhering to the copper foil layer, thereby blocking moisture from the outside.

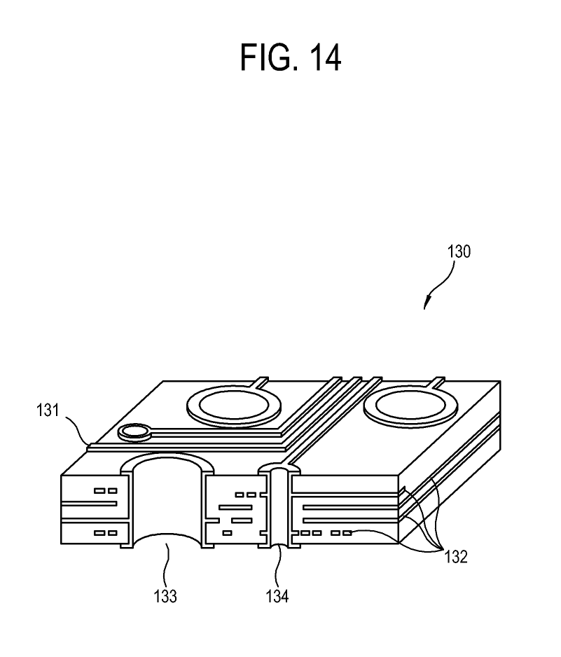

FIG. 14 illustrates a textile fiber material and a resin material respectively applied to an upper layer and a lower layer among a plurality of layers of the multi-layered PCB according to an exemplary embodiment. As shown in FIG. 14, a multi-layered PCB 130 has a 3D structure with an inner layer circuit and an outer layer circuit, and has high mounting density and short wiring distance due to 3D wiring lines. The multi-layered PCB 130 may be for example applied to a large computer, a personal computer, a communication device, small home appliances, etc. A plurality of layers in the multi-layered PCB 130 may be each achieved by a copper foil laminated plate of the double-sided PCB. Further, the plurality of layers may be each achieved by the CEM-1 material using the textile fiber.

The multi-layered PCB 130 includes a plurality of copper foil laminated plates including an inner layer circuit 132, a copper foil layer printed with a pattern of an outer layer circuit 131, and a through hole 133 through which parts are mounted by connecting with the outer layer circuit 131. Further, the multi-layered PCB 130 includes a VIA hole 134 through which the outer layer circuit 131 and the inner layer circuit 132 are connected.

According to an exemplary embodiment, each copper foil laminated plate having the inner layer circuit 132 in the multi-layered PCB 130 includes a base layer having a plurality of paper layers impregnated with epoxy resin, a waterproof insulation layer made of a textile fiber material and laid on one side of the base layer, and a waterproof adhesive layer interposed in between the base layer and the copper foil and containing an epoxy resin material for adhesion between the base layer and the copper foil. Here, the waterproof adhesive layer may further include a resin material for waterproofing. The waterproof insulation layer may include the epoxy resin material.

Thus, the multi-layered PCB 130 includes the plurality of copper foil laminated plates, each of which employs the textile fiber material on one side and employs the waterproof adhesive layer of the resin material on the other side for adhering to the copper foil, thereby blocking moisture from the outside.

As described above, a printed circuit board according to an exemplary embodiment employs an insulation layer of a textile fiber material and a waterproof adhesive layer to an upper layer and a lower layer of a substrate, respectively, thereby preventing insulating properties from changing due to moisture.

Further, according to an exemplary embodiment, the resin material having both the waterproof and adhesive functions are used to form the lower layer of the printed circuit board instead of the textile fiber material, thereby having an effect on reducing the manufacturing costs of the printed circuit board.

Although a few exemplary embodiments have been shown and described, it will be appreciated by those skilled in the art that changes may be made in these exemplary embodiments without departing from the principles and spirit of the invention, the scope of which is defined in the appended claims and their equivalents.

What is claimed is:

1. A printed circuit board, to which at least one circuit device is mountable, comprising:
a base layer comprising a plurality of paper layers;
a waterproof insulation layer laid on a first surface of the base layer;
a copper foil layer laid on a second surface opposite to the first surface of the base layer and printed with a signal line pattern connectable with the at least one circuit device; and
an adhesive layer interposed between the base layer and the copper foil layer and comprising an adhesive material that adheres the base layer and the copper foil layer.

2. The printed circuit board according to claim 1, wherein the waterproof insulation layer comprises a textile fiber material.

3. The printed circuit board according to claim 1, wherein the adhesive layer is waterproof and comprises a waterproof material.

4. The printed circuit board according to claim 3, wherein the waterproof material comprises an insulating resin material.

5. The printed circuit board according to claim 1, wherein the adhesive material comprises a semi-hardening epoxy resin material.

6. The printed circuit board according to claim 3, wherein the adhesive layer is formed as a single layer by combining the adhesive material and the waterproof material.

7. The printed circuit board according to claim 3, wherein the adhesive layer is hardened by heating at high temperature to stick together the base layer and the copper foil layer.

8. The printed circuit board according to claim 3, wherein the waterproof insulation layer and the adhesive layer each comprise an insulating material with a comparative tracking index (CTI) equal to or higher than 600 V.

9. The printed circuit board according to claim 1, wherein the base layer further comprises an epoxy resin material.

10. An electronic apparatus with a printed circuit board comprising a power supply for receiving an alternating current power signal and supplying operation power to the electronic apparatus, the printed circuit board comprising:
a base layer comprising a plurality of paper layers;
a waterproof insulation layer laid on a first surface of the base layer;
a copper foil layer laid on a second surface opposite to the first surface of the base layer and printed with a signal line pattern connectable with the at least one circuit device; and
an adhesive layer interposed between the base layer and the copper foil layer and comprising an adhesive material that adheres the base layer and the copper foil layer.

11. The electronic apparatus according to claim 10, wherein the waterproof insulation layer comprises a textile fiber material.

12. The electronic apparatus according to claim 10, wherein the adhesive layer is waterproof and comprises a waterproof material.

13. The electronic apparatus according to claim 12, wherein the waterproof material comprises an insulating resin material.

14. The electronic apparatus according to claim 10, wherein the adhesive material comprises a semi-hardening epoxy resin material.

15. The electronic apparatus according to claim 12, wherein the adhesive layer is formed as a single layer by combining the adhesive material and the waterproof material.

16. The electronic apparatus according to claim 12, wherein the adhesive layer is hardened by heating at high temperature to stick together the base layer and the copper foil layer.

17. The electronic apparatus according to claim 12, wherein the waterproof insulation layer and the adhesive layer each comprise an insulating material with a comparative tracking index (CTI) equal to or higher than 600 V.

18. The electronic apparatus according to claim 10, wherein the base layer comprises an epoxy resin material.
